(19) United States
(12) Patent Application Publication
(10) Pub. No.: US 2023/0043696 A1
(43) Pub. Date: Feb. 9, 2023

(54) METHOD AND APPARATUS FOR MANUFACTURING SEMICONDUCTOR DEVICE AND METHOD AND SYSTEM FOR EXPOSING SEMICONDUCTOR

(71) Applicant: CHANGXIN MEMORY TECHNOLOGIES, INC., Hefei City (CN)

(72) Inventor: Jie Du, Hefei City (CN)

(73) Assignee: CHANGXIN MEMORY TECHNOLOGIES, INC., Hefei City (CN)

(21) Appl. No.: 17/452,089

(22) Filed: Oct. 25, 2021

Related U.S. Application Data
(63) Continuation of application No. PCT/CN2021/113626, filed on Aug. 19, 2021.

(30) Foreign Application Priority Data
Aug. 9, 2021 (CN) 202110906604.2

(51) Int. Cl. G03F 7/20; G03F 1/70

(52) U.S. Cl. CPC G03F 7/70625; G03F 1/70; G03F 7/2026; G03F 7/70641; G03F 7/7055

(57) ABSTRACT

A method for manufacturing a semiconductor device includes: providing a semiconductor wafer, and acquiring surface flatness information of the semiconductor wafer; determining an exposure parameter of the semiconductor wafer according to the surface flatness information of the semiconductor wafer; and exposing the semiconductor wafer according to the exposure parameter.

### CROSS-REFERENCE TO RELATED APPLICATIONS

This is a continuation of International Patent Application No. PCT/CN2021/113626 filed on Aug. 19, 2021, which claims priority to Chinese Patent Application No. 202110906604.2 filed Aug. 9, 2021. The disclosures of the above-referenced applications are hereby incorporated by reference in their entirety.

### BACKGROUND

Photolithography is a process of uniformly applying a photoresist on a surface of a silicon wafer and then transferring a pattern on a mask to the photoresist, to temporarily “copy” a device or circuit structure onto the silicon wafer. The photolithography is a common process of manufacturing a semiconductor device. The acquisition of adequate critical dimension (CD) uniformity in the photolithography greatly affects the performance and yield of semiconductor devices.

### SUMMARY

The present disclosure relates to the field of integrated circuit manufacturing technologies, and more specifically to a method and an apparatus for manufacturing a semiconductor device and method and system for exposing a semiconductor.

Embodiment of the present disclosure provide a method and an apparatus for manufacturing a semiconductor device and a method and system for exposing a semiconductor, so that in a process of photolithography, an energy dose sub recipe of each wafer is determined by using a surface flatness of the wafer, thereby improving wafer CD uniformity and reducing material costs.

According to a first aspect, the present disclosure provides a method for manufacturing a semiconductor device, including: providing a semiconductor wafer, and acquiring surface flatness information of the semiconductor wafer; determining an exposure parameter of the semiconductor wafer according to the surface flatness information of the semiconductor wafer; and exposing the semiconductor wafer according to the exposure parameter.

According to a second aspect, the present disclosure provides a method for exposing a semiconductor, including: providing a semiconductor wafer, and acquiring surface flatness information of the semiconductor wafer; exposing the semiconductor wafer under a preset exposure condition, to acquire a feature pattern; measuring the feature pattern, to acquire a feature dimension of the feature pattern; and determining whether the feature dimension satisfies a preset condition; when the feature dimension satisfies the preset condition, continuing to expose the subsequent semiconductor wafer according to the preset exposure condition; and when the feature dimension does not satisfy the preset condition, selecting a feature pattern having an outlier feature dimension, finding a surface flatness corresponding to a region of the feature pattern, modifying the preset exposure condition of the feature pattern having the outlier feature dimension according to the surface flatness, and exposing the subsequent semiconductor wafer according to the modified preset exposure condition.

According to a third aspect, the present disclosure provides an apparatus for manufacturing a semiconductor device, including: a processor, configured to acquire surface flatness information of a semiconductor wafer after the semiconductor wafer is provided, and determine an exposure parameter of the semiconductor wafer according to the surface flatness information of the semiconductor wafer; and an exposure implementation device, configured to expose the semiconductor wafer according to the exposure parameter.

According to a fourth aspect, the present disclosure provides a semiconductor exposure system, including: a memory, configured to store data or program code used to run the semiconductor exposure system; and a processor, configured to: provide a semiconductor wafer, and acquire surface flatness information of the semiconductor wafer; expose the semiconductor wafer under a preset exposure condition, to acquire a feature pattern; measure the feature pattern, to acquire a feature dimension of the feature pattern; and determine whether the feature dimension satisfies a preset condition; when the feature dimension satisfies the preset condition, continue to expose the subsequent semiconductor wafer according to the preset exposure condition; and when the feature dimension does not satisfy the preset condition, select a feature pattern having an outlier feature dimension, find a surface flatness corresponding to a region of the feature pattern, modify the preset exposure condition of the feature pattern having the outlier feature dimension according to the surface flatness, and expose the subsequent semiconductor wafer according to the modified preset exposure condition.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a flowchart of a method for manufacturing a semiconductor device according to an embodiment of the present disclosure;

FIG. 2 is a schematic diagram of a surface flatness of an exposure region of a semiconductor wafer according to an embodiment of the present disclosure;

FIG. 3 is a flowchart of determining target exposure energy for exposing an exposure region according to an embodiment of the present disclosure;

FIG. 4 is a schematic diagram of a correspondence relationship between a focus depth and exposure energy according to an embodiment of the present disclosure;

FIG. 5 is a flowchart of a method for exposing a semiconductor according to an embodiment of the present disclosure;

FIG. 6 is a schematic structural diagram of an apparatus for manufacturing a semiconductor device according to an embodiment of the present disclosure; and

FIG. 7 is a schematic structural diagram of a semiconductor exposure system according to an embodiment of the present disclosure.

### DETAILED DESCRIPTION

To make the objectives, technical solutions, and advantages of the present disclosure clearer, the present disclosure is further described below in detail with reference to the accompanying drawings. Apparently, the described embodiments are merely some rather than all of the embodiments of the present disclosure. All other embodiments obtained by those ordinary skilled in the art based on the embodiments of the present disclosure without creative efforts fall within the protection scope of the present disclosure.

In the embodiments of the present disclosure, the word “exemplary” herein means “serving as an example, an embodiment, or an illustration”. Any embodiment described herein as “exemplary” does not need to be construed as being superior or better than other embodiments.

The terms “first” and “second” herein are used only for description, but are not intended to indicate or imply relative importance or implicitly specify a quantity of indicated technical features. Therefore, features defined by “first” and “second” may explicitly or implicitly include one or more features. In the embodiments of the present disclosure, “a plurality of” herein means “two or more” unless otherwise described.

Some terms in the embodiments of the present disclosure are explained and described below to be better understood by those skilled in the art.

(1) A wafer is formed by pure silicon (Si), and may have a size of 6 inches, 8 inches, 12 inches or the like. A chip is produced based on the wafer. The wafer is a silicon chip used for manufacturing a silicon semiconductor integrated circuit, and is termed so for its circular shape. Various circuit element structures may be processed and manufactured on the silicon chip, to form an integrated circuit product with specific electrical functions.

(2) A wafer CD (a wafer/shot CD) is a CD of a photolithographic pattern on a wafer. For example, corresponding to a wafer including a word line pattern in a flash storage unit, the wafer CD is a dimension of a word line/line width. Corresponding to a wafer in which a trench pattern is formed, the wafer CD is a dimension of a trench.

(3) A wafer CD uniformity (Wafer/shot CD uniformity) is an overall difference degree of a wafer CD of a wafer. If an overall difference degree of a wafer CD of a wafer is relatively small, it indicates that the wafer CD is controlled adequately, and the wafer CD uniformity is adequate.

Photolithography is a process of uniformly applying a photoresist on a surface of a silicon wafer and then transferring a pattern on a mask to the photoresist, to temporarily “copy” a device or circuit structure onto the silicon wafer. The photolithography is a common process of manufacturing a semiconductor device. The acquisition of adequate CD uniformity in the photolithography greatly affects the performance and yield of semiconductor devices.

At present, to improve wafer CD uniformity in photolithography, a CD-SEM is mainly used to measure wafer CD uniformity of one wafer, to obtain an energy dose sub recipe, and subsequently the “fixed” energy dose sub recipe is repeatedly used for compensation.

Typically, the “fixed” energy dose sub recipe is used for energy compensation. Although CD uniformity can be increased to a particular degree, the effect is unsatisfactory. For example, if a current process is changed, when compensation is performed according to the “fixed” energy dose sub recipe, a relatively large difference occurs after photolithography, resulting in increased raw material costs.

The present disclosure provides a method and an apparatus for manufacturing a semiconductor device and a method and system for exposing a semiconductor, to resolve a problem that in a process of manufacturing a semiconductor device in the related art, the effect of improving CD uniformity is unsatisfactory, leading to high raw material costs. The method for manufacturing a semiconductor device includes: providing a semiconductor wafer, and acquiring surface flatness information of the semiconductor wafer; determining an exposure parameter of the semiconductor wafer according to the surface flatness information of the semiconductor wafer; and exposing the semiconductor wafer according to the exposure parameter. Compared with compensation repeatedly using a fixed energy compensation value during photolithography in the related art, in the method, surface flatness information of each semiconductor wafer is determined by using surface levelness data of the semiconductor wafer, and target exposure energy for exposing each semiconductor wafer is determined, so that exposure control is performed on each wafer according to corresponding target exposure energy. Therefore, an energy dose sub recipe that changes in real time can be applied to semiconductor wafers, and exposure control during photolithography of semiconductor wafers is finer, so that wafer CD uniformity can be significantly improved, the yield of semiconductor devices can be increased, and material costs of a process of manufacturing a semiconductor device can be reduced.

To further describe the technical solutions provided in the embodiments of the present disclosure, the method for manufacturing a semiconductor device provided in the embodiments of the present disclosure is further described below.

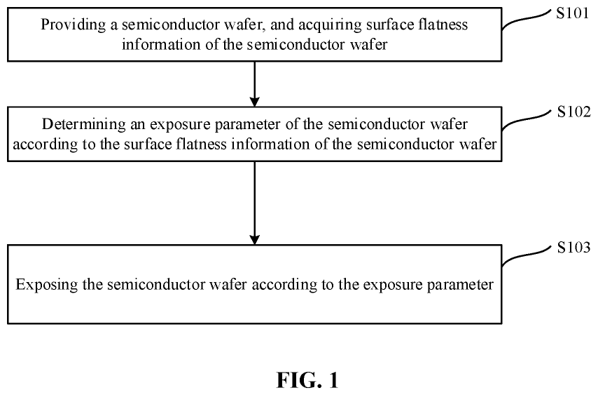

FIG. 1 is a schematic flowchart of a method for manufacturing a semiconductor device according to an embodiment of the present disclosure. As shown in FIG. 1, the method for manufacturing a semiconductor device may include the following steps.

In step S101, a semiconductor wafer is provided, and surface flatness information of the semiconductor wafer is acquired.

Specifically, the semiconductor wafer is provided, and before the semiconductor wafer is exposed, the surface flatness information of the semiconductor wafer is acquired and stored in a preset database.

It may be understood that the surface flatness information of the semiconductor wafer may be an average flatness of the entire semiconductor wafer or may be a surface flatness of a partial region of the semiconductor wafer. A specific form of the surface flatness information of the semiconductor wafer is not specifically limited in the present disclosure. In the embodiments of the present disclosure, the partial region of the semiconductor wafer may also be referred to as an exposure region of the semiconductor wafer.

In an optional implementation, the semiconductor wafer includes a plurality of exposure regions, and the acquiring surface flatness information of the semiconductor wafer may be acquiring surface flatness information of the exposure regions of the semiconductor wafer.

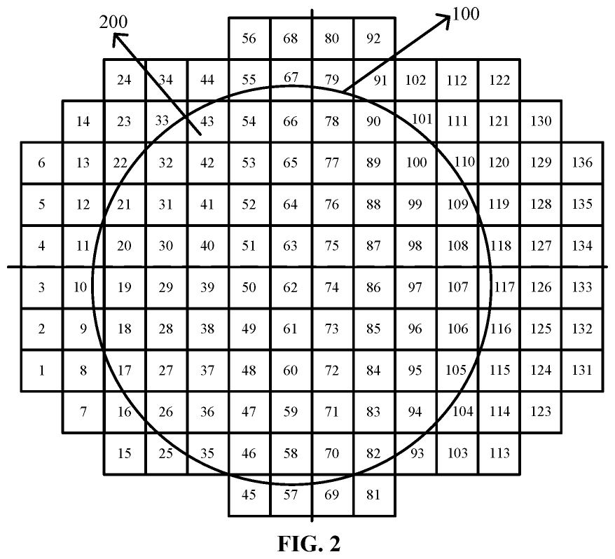

For example, the acquiring surface flatness information of the semiconductor wafer may be acquiring surface flatness information and position information of the exposure region of the semiconductor wafer, for example, may acquire a surface flatness of an exposure region shown in FIG. 2, to acquire the surface flatness information of the exposure region. As shown in FIG. 2, a semiconductor wafer 100 includes a plurality of exposure regions 200. In some embodiments, the surface flatness information of the exposure region may be distinguishingly represented by different colors in FIG. 2.

Optionally, during the acquiring surface flatness information of the semiconductor wafer, the surface flatness information and position information of the exposure regions of the semiconductor wafer may further be acquired. The position information of the exposure region of the semiconductor wafer is a preset position number corresponding to the exposure region. For example, as shown in FIG. 2, position information of the exposure regions 200 of the semiconductor wafer 100 is preset position numbers corresponding to the exposure regions, for example, preset position numbers of 43, 54, 66, and the like in FIG. 2.

In a specific implementation, the surface flatness information of the exposure region of the semiconductor wafer is obtained by using a surface flatness measurement tool. Preset position numbers corresponding to virtual blocks of the semiconductor wafer are set for the semiconductor wafer in the surface flatness measurement tool. The virtual blocks of the semiconductor wafer are the exposure regions of the semiconductor wafer. The position information may be represented by preset position numbers of the virtual blocks corresponding to the exposure regions.

In the foregoing method, the semiconductor wafer includes a plurality of exposure regions, and the acquiring surface flatness information of the semiconductor wafer is specifically acquiring the surface flatness information of the exposure regions of the semiconductor wafer. In the method, the surface flatness information of the exposure region of the semiconductor wafer may be acquired, so that an energy dose sub recipe that changes in real time can be applied to the exposure regions of each semiconductor wafer, and finer exposure control can be performed on the semiconductor wafer, thereby further improving wafer CD uniformity, increasing the yield of semiconductor devices, and reducing material costs of a process of manufacturing a semiconductor device.

In step S102, an exposure parameter of the semiconductor wafer is determined according to the surface flatness information of the semiconductor wafer.

In a possible implementation, the semiconductor wafer has a preset exposure parameter, and the determining an exposure parameter of the semiconductor wafer according to the surface flatness information of the semiconductor wafer is specifically: modifying the preset exposure parameter according to the surface flatness information, to obtain the exposure parameter.

For example, the semiconductor wafer has the preset exposure parameter. For example, the preset exposure parameter is a preset lens focus value used for exposing the semiconductor wafer, and a modified focus value of the semiconductor wafer may be determined by using a lens focus value of the semiconductor wafer and the surface flatness information of the semiconductor wafer. Target exposure energy for performing exposure is determined by the modified focus value. For example, assuming that the preset lens focus value used for exposing the semiconductor wafer is −0.16 um and the surface flatness information of the semiconductor wafer is −0.02 um, by using a lens focus value of −0.16 um of the semiconductor wafer and the surface flatness information of −0.02 um of the semiconductor wafer, it may be determined that the modified focus value of the semiconductor wafer is −0.18 um.

In the foregoing method, the semiconductor wafer has the preset exposure parameter; and the determining an exposure parameter of the semiconductor wafer according to the surface flatness information of the semiconductor wafer includes: modifying the preset exposure parameter according to the surface flatness information, to obtain the exposure parameter. In the method, the preset exposure parameter is modified in combination with the surface flatness information, to increase wafer CD uniformity, thereby reducing material costs.

In an optional implementation, the preset exposure parameter includes a first focus depth and first exposure energy that are preset according to a target CD; and the modifying the preset exposure parameter according to the surface flatness information, to obtain the exposure parameter includes: modifying the first focus depth into a second focus depth according to the surface flatness information, and modifying the first exposure energy into second exposure energy according to the target CD and the second focus depth.

Specifically, the target exposure energy of the semiconductor wafer corresponding to the second focus depth may be determined according to a prestored correspondence relationship between a focus depth and exposure energy.

In the embodiments of the present disclosure, the correspondence relationship between a focus depth and exposure energy is prestored. In some embodiments, the prestored correspondence relationship between a focus depth and exposure energy is Focus & Energy Matrix (FEM). In the FEM, the horizontal coordinate is the focus value, and the vertical coordinate is wafer CD uniformity.

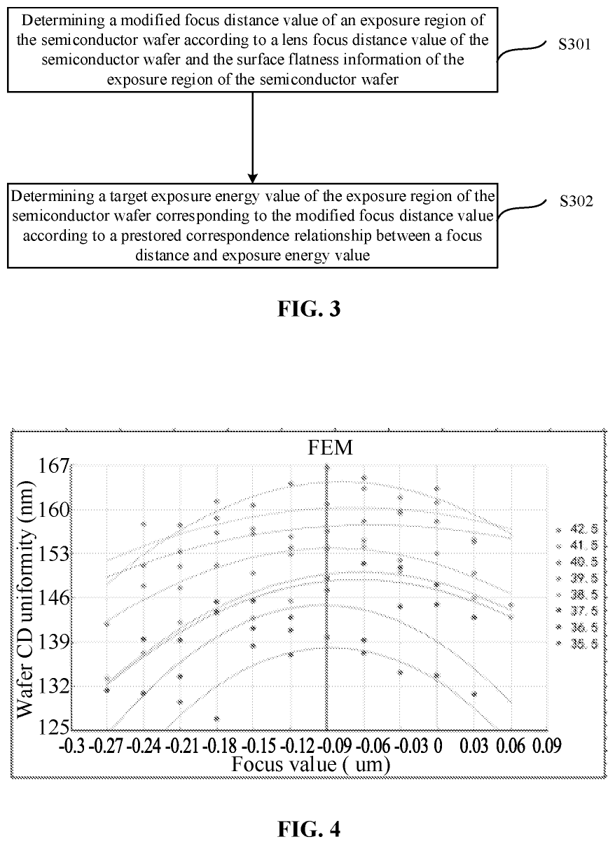

For example, the first focus depth preset according to the target CD may be the preset lens focus value used for exposing the semiconductor wafer, preset first exposure energy may be nominal exposure energy that is determined according to the FEM and corresponds to the target CD and the lens focus value. The modifying the preset exposure parameter according to the surface flatness information, to obtain the exposure parameter may be implemented by using the following step: modifying the lens focus value into the modified focus value according to the surface flatness information, and modifying the nominal exposure energy into the target exposure energy according to the target CD and the modified focus value. For example, according to a prestored FEM shown in FIG. 4, it is assumed that the target CD to be reached is 155 nm, and target exposure energy of the current semiconductor wafer corresponding to the modified focus value of −0.10 um is determined, for example, is 39.5.

In the foregoing method, the preset exposure parameter includes a first focus depth and first exposure energy that are preset according to a target CD; and the first focus depth is modified into the second focus depth according to the surface flatness information, and the first exposure energy is modified into the second exposure energy according to the target CD and the second focus depth. In the method, the first focus depth is modified into the second focus depth according to the surface flatness information, and the first exposure energy is modified into the second exposure energy according to the target CD and the second focus depth, so that an accurate energy dose sub recipe may be determined for each semiconductor wafer, thereby improving wafer CD uniformity of a photolithography process and reducing material costs.

In an optional implementation, each of the exposure regions has the preset exposure parameter; and the modifying the preset exposure parameter according to the surface flatness information, to obtain the exposure parameter includes: modifying the preset exposure parameters of the exposure regions respectively according to the surface flatness information of the exposure regions.

During a specific implementation, the preset exposure parameter may include the preset lens focus value used for exposing the semiconductor wafer. The modified focus value of the exposure region of the semiconductor wafer may be determined by using the lens focus value of the semiconductor wafer and the surface flatness information of the exposure region of the semiconductor wafer. The target exposure energy for exposing an exposure region is determined by using the modified focus value of the exposure region.

In the embodiments of the present disclosure, the first focus depth may be referred to as a lens focus value, the second focus depth may be referred to as the modified focus value, the first exposure energy may be referred to as nominal exposure energy, and the second exposure energy may be referred to as the target exposure energy.

In the foregoing method, each of the exposure regions has the preset exposure parameter; and the preset exposure parameters of the exposure regions are respectively modified according to the surface flatness information of the exposure regions. In the method, finer exposure control can be performed according to exposure parameters obtained by modifying the preset exposure parameters of the exposure regions respectively, so that wafer CD uniformity can be improved, the yield of semiconductor devices can be increased, and material costs of a process of manufacturing a semiconductor device can be reduced.

In a possible implementation, as shown in FIG. 3, the determining, by using the lens focus value of the semiconductor wafer and the surface flatness information of the exposure region of the semiconductor wafer, the target exposure energy for exposing an exposure region may be specifically implemented by using the following steps:

In step S301, a modified focus value of an exposure region of the semiconductor wafer is determined according to a lens focus value of the semiconductor wafer and the surface flatness information of the exposure region of the semiconductor wafer.

For example, it is assumed that the current lens focus value is −0.09 um and current surface flatness information of the exposure region with the position information of 21 of the semiconductor wafer is −0.01 um, the modified focus value of the exposure region with the position information of 21 of the current semiconductor wafer is −0.10 um.

In step S302, target exposure energy of the exposure region of the semiconductor wafer corresponding to the modified focus value is determined according to a prestored correspondence relationship between a focus depth and exposure energy.

Specifically, the prestored correspondence relationship between a focus depth and exposure energy may be a FEM. In the FEM, the horizontal coordinate is the modified focus value of an exposure machine, and the vertical coordinate is wafer CD uniformity.

For example, according to the prestored FEM shown in FIG. 4, assuming that the wafer CD uniformity to be reached is 155 nm, target exposure energy of an exposure region with the position information of 21 of the current semiconductor wafer corresponding to the modified focus value of −0.10 um is determined. For example, the obtained target exposure energy may be 39.5. The obtained target exposure energy is different from nominal exposure energy corresponding to the lens focus value of −0.09 um.

In the method shown in FIG. 3, the modified focus value of the exposure region of the semiconductor wafer is determined according to the lens focus value of the semiconductor wafer and the surface flatness information of the exposure region of the semiconductor wafer; and the target exposure energy of the exposure region of the semiconductor wafer corresponding to the modified focus value is determined according to the prestored correspondence relationship between a focus depth and exposure energy. The modified focus value of the exposure region of the semiconductor wafer is determined according to the lens focus value of the semiconductor wafer and the surface flatness information of the exposure region of the semiconductor wafer, to determine the target exposure energy of the exposure region corresponding to the modified focus value, so that an energy dose sub recipe can be accurately determined for the exposure region of each semiconductor wafer, thereby increasing the wafer CD uniformity of a photolithography process and reducing material costs.

In step S103, the semiconductor wafer is exposed according to the exposure parameter.

Specifically, the exposing the semiconductor wafer according to the exposure parameter may be exposing the semiconductor wafer according to the exposure parameter determined by using the average flatness of the entire semiconductor wafer; or may be exposing the exposure regions of the semiconductor wafer according to the exposure parameter determined by using the surface flatness of the exposure region of the semiconductor wafer.

In an optional implementation, the exposing the semiconductor wafer according to the exposure parameter is specifically exposing the semiconductor wafer according to the second focus depth and the second exposure energy.

For example, the second focus depth of the current semiconductor wafer is −0.10 um, and the second exposure energy of the exposure region with the position information of 21 of the current semiconductor wafer is 39.5. The exposure region with the position information of 21 of the current semiconductor wafer is exposed according to the second focus depth of −0.10 um and the second exposure energy of 39.5.

By using the method shown in FIG. 1, a semiconductor wafer is provided, and surface flatness information of the semiconductor wafer is acquired; an exposure parameter of the semiconductor wafer is determined according to the surface flatness information of the semiconductor wafer; and the semiconductor wafer is exposed according to the exposure parameter. Compared with compensation repeatedly using a fixed energy compensation value during photolithography in the related art, surface flatness information of each semiconductor wafer is determined by using surface levelness data of the semiconductor wafer, and target exposure energy for exposing each semiconductor wafer is determined, so that exposure control is performed on each wafer according to corresponding target exposure energy. Therefore, an energy dose sub recipe that changes in real time can be applied to semiconductor wafers, and exposure control during photolithography of semiconductor wafers is finer, so that wafer CD uniformity can be significantly improved, the yield of semiconductor devices can be increased, and material costs of a process of manufacturing a semiconductor device can be reduced.

In a possible implementation, after the exposing the semiconductor wafer according to the exposure parameter, a subsequent process such as an etching process is performed on the semiconductor wafer.

In the foregoing method, after the exposing the semiconductor wafer according to the exposure parameter, a subsequent process is performed on the semiconductor wafer. The exposure region of the semiconductor wafer is exposed according to the position information and target exposure energy of the exposure region, and a plurality of subsequent processes may be combined to increase wafer CD uniformity, thereby reducing material costs.

In an optional embodiment of the present disclosure, an alignment mark is disposed on the semiconductor wafer, and the subsequent processes include alignment measurement.

During a specific implementation, the alignment mark is disposed on the semiconductor wafer, and after the exposure region of the semiconductor wafer is exposed according to the position information and target exposure energy of the exposure region, the alignment measurement is performed according to the alignment mark, to evaluate alignment precision between a current layer and a previous layer. If the alignment precision is less than a preset specification, the current layer of the semiconductor wafer needs to be reworked.

In an optional embodiment of the present disclosure, the subsequent processes further include feature dimension measurement. After the alignment measurement, the feature dimension measurement is further performed, and a measurement result of the feature dimension measurement is stored in a database. The measurement result is used for evaluating the manufacturing quality of a semiconductor device.

In an optional embodiment of the present disclosure, according to the measurement result of the feature dimension measurement, a first preset quantity of most recent abnormal measurement results are monitored. If it is detected that the first preset quantity of consecutive measurement results are abnormal, manufacturing anomaly alarm information is sent.

In the foregoing method, if it is detected that the first preset quantity of consecutive measurement results are abnormal, the manufacturing anomaly alarm information is sent, so that a large batch of semiconductor devices with a relatively large deviation can be effectively prevented, thereby avoiding a production waste and reducing material costs.

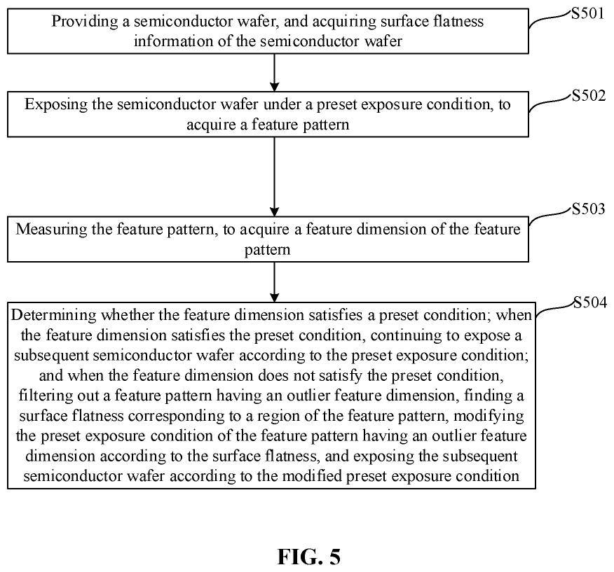

Based on the same inventive concept, the embodiments of the present disclosure further provide a method for exposing a semiconductor. As shown in FIG. 5, the method may include the following steps.

In step S501, a semiconductor wafer is provided, and surface flatness information of the semiconductor wafer is acquired.

Specifically, the semiconductor wafer is provided, and before the semiconductor wafer is exposed, the surface flatness information of the semiconductor wafer is acquired and stored in a preset database.

It may be understood that the surface flatness information of the semiconductor wafer may be an average flatness of the entire semiconductor wafer or may be a surface flatness of an exposure region of the semiconductor wafer. A specific form of the surface flatness information of the semiconductor wafer is not specifically limited in the present disclosure.

In step S502, the semiconductor wafer is exposed under a preset exposure condition, to acquire a feature pattern.

In step S503, the feature pattern is measured, to acquire a feature dimension of the feature pattern.

In step S504, it is determined whether the feature dimension satisfies a preset condition; when the feature dimension satisfies the preset condition, the subsequent semiconductor wafer continues to be exposed according to the preset exposure condition; and when the feature dimension does not satisfy the preset condition, a feature pattern having an outlier feature dimension is filtered out, a surface flatness corresponding to a region of the feature pattern is found out, the preset exposure condition of the feature pattern having the outlier feature dimension is modified according to the surface flatness, and the subsequent semiconductor wafer is exposed according to the modified preset exposure condition.

Compared with compensation repeatedly using a fixed energy compensation value during photolithography in the related art, the semiconductor wafer may be exposed under a preset exposure condition, to acquire the feature pattern; the feature pattern is measured, to acquire the feature dimension of the feature pattern; it is determined whether the feature dimension satisfies a preset condition; when the feature dimension satisfies the preset condition, the subsequent semiconductor wafer continues to be exposed according to the preset exposure condition; and when the feature dimension does not satisfy the preset condition, the feature pattern having the outlier feature dimension is filtered out, a surface flatness corresponding to a region of the feature pattern is found out, the preset exposure condition of the feature pattern having the outlier feature dimension is modified according to the surface flatness, and the subsequent semiconductor wafer is exposed according to the modified preset exposure condition. In the method, an energy dose sub recipe that changes in real time can be applied to semiconductor wafers, so that finer exposure control can be performed during photolithography of semiconductor wafers, and the preset exposure condition can be further modified, thereby further improving wafer CD uniformity, increasing the yield of semiconductor devices, and reducing material costs of a process of manufacturing a semiconductor device.

In an optional implementation, the preset exposure condition includes a first focus depth and first exposure energy that are preset according to a target CD; and the modifying the preset exposure condition of the feature pattern having the outlier feature dimension according to the surface flatness may be specifically: modifying the first focus depth of the feature pattern having the outlier feature dimension into a second focus depth according to the surface flatness information, and modifying the first exposure energy of the feature pattern having the outlier feature dimension into second exposure energy according to the target CD and the second focus depth.

In an optional implementation, the exposing the subsequent semiconductor wafer according to the modified preset exposure condition includes: exposing the subsequent semiconductor wafer according to the second focus depth and the second exposure energy.

In an optional implementation, the semiconductor wafer includes a plurality of exposure regions, and the exposure regions have the preset exposure condition; and the finding a surface flatness corresponding to a region of the feature pattern, modifying the preset exposure condition of the feature pattern having the outlier feature dimension according to the surface flatness, and exposing the subsequent semiconductor wafer according to the modified preset exposure condition includes:

acquiring surface flatness information of the exposure regions corresponding to the region of the feature pattern respectively, and modifying the preset exposure conditions of the exposure regions corresponding to the feature pattern having the outlier feature dimension respectively according to the surface flatness information of the exposure regions corresponding to the region of the feature pattern; and

exposing the subsequent semiconductor wafer according to the modified preset exposure condition.

For a specific process of step S501 to step S504, reference may be made to the execution of the method steps in the foregoing embodiments. Details are not described herein again.

Based on the same inventive concept of the method shown in FIG. 1 for manufacturing a semiconductor device, an embodiment of the present disclosure further provides an apparatus for manufacturing a semiconductor device. Because the apparatus is an apparatus corresponding to the method for manufacturing a semiconductor device in the present disclosure, and the principle of resolving the problem of the apparatus is similar to that of the method, for the implementation of the apparatus, reference may be made to the implementation of the foregoing method. Details are not repeated.

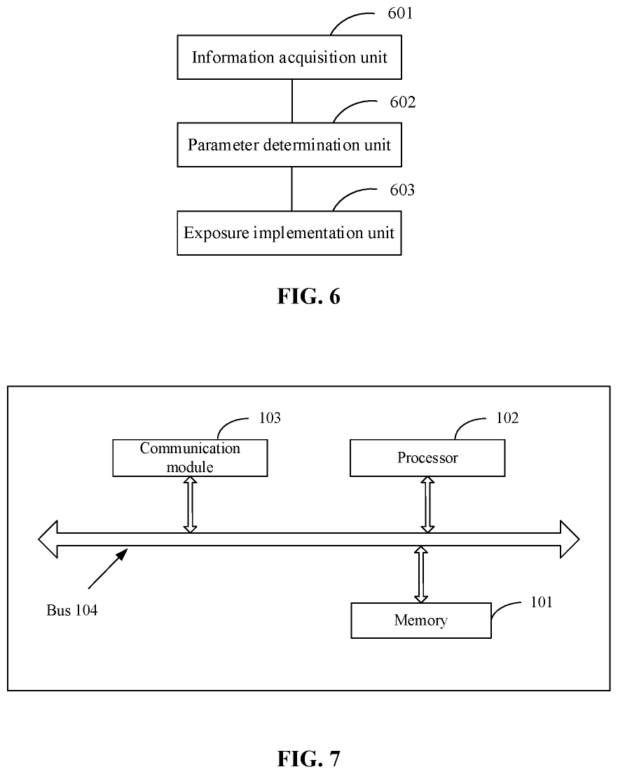

FIG. 6 is a schematic structural diagram of an apparatus for manufacturing a semiconductor device according to an embodiment of the present disclosure. As shown in FIG. 6, the apparatus for manufacturing a semiconductor device includes an information acquisition unit 601, a parameter determination unit 602, and an exposure implementation unit 603.

The information acquisition unit 601 is configured to acquire surface flatness information of a semiconductor wafer after the semiconductor wafer is provided.

The parameter determination unit 602 is configured to determine an exposure parameter of the semiconductor wafer according to the surface flatness information of the semiconductor wafer.

The exposure implementation unit 603 is configured to expose the semiconductor wafer according to the exposure parameter.

In an optional embodiment, the semiconductor wafer has a preset exposure parameter, and the parameter determination unit 602 is configured to modify the preset exposure parameter according to the surface flatness information, to obtain the exposure parameter.

In an optional embodiment, the preset exposure parameter includes a first focus depth and first exposure energy that are preset according to a target CD; and the parameter determination unit 602 is configured to: modify the first focus depth into a second focus depth according to the surface flatness information, and modify the first exposure energy into second exposure energy according to the target CD and the second focus depth.

In an optional embodiment, the semiconductor wafer includes a plurality of exposure regions; and the information acquisition unit 601 is configured to acquire surface flatness information of the exposure regions of the semiconductor wafer.

In an optional embodiment, each of the exposure regions has the preset exposure parameter; and the parameter determination unit 602 is configured to modify the preset exposure parameters of the exposure regions respectively according to the surface flatness information of the exposure regions.

Based on the same inventive concept as the method for exposing a semiconductor shown in FIG. 5, an embodiment of the present disclosure further provides a semiconductor exposure system. Because the system is a system corresponding to the method for exposing a semiconductor in the present disclosure, and the principle of resolving the problem of the system is similar to that of the method, for the implementation of the system, reference may be made to the implementation of the foregoing method. Details are not repeated.

FIG. 7 is a schematic structural diagram of a semiconductor exposure system according to an embodiment of the present disclosure. As shown in FIG. 7, the semiconductor exposure system includes a memory 101, a communication module 103, and one or more processors 102.

The memory 101 is configured to store a computer program performed by the processor 102. The memory 101 may mainly include a program storage region and a data storage region. The program storage region may store an operating system and a program required for running an instant messaging function, and the like. The data storage region may store various instant messaging information, an operation instruction set, and the like.

The memory 101 may be a volatile memory, for example, a random access memory (RAM). The memory 101 may be alternatively a non-volatile memory, for example, read-only memory, a flash memory, a hard disk drive (HDD) or a solid-state drive (SSD). Alternatively, the memory 101 is any other medium that can be configured to carry or store an expected program code having the form of an instruction or data structure and can be accessed by a computer, but is not limited thereto. The memory 101 may be a combination of the foregoing memories.

The processor 102 may include one or more central processing units (CPUs), digital processing units, and the like.

The processor 102 is configured to:

provide a semiconductor wafer, and acquire surface flatness information of the semiconductor wafer;

expose the semiconductor wafer under a preset exposure condition, to acquire a feature pattern;

measure the feature pattern, to acquire a feature dimension of the feature pattern;

determine whether the feature dimension satisfies a preset condition; when the feature dimension satisfies the preset condition, continue to expose the subsequent semiconductor wafer according to the preset exposure condition; and when the feature dimension does not satisfy the preset condition, select a feature pattern having an outlier feature dimension, find a surface flatness corresponding to a region of the feature pattern, modify the preset exposure condition of the feature pattern having the outlier feature dimension according to the surface flatness, and expose the subsequent semiconductor wafer according to the modified preset exposure condition.

In an optional embodiment, the preset exposure condition includes a first focus depth and first exposure energy that are preset according to a target CD; and the processor 102 is configured to:

modify the first focus depth of the feature pattern having the outlier feature dimension into a second focus depth according to the surface flatness information, and modify the first exposure energy of the feature pattern having the outlier feature dimension into second exposure energy according to the target CD and the second focus depth.

In an optional embodiment, the processor 102 is configured to:

expose the subsequent semiconductor wafer according to the second focus depth and the second exposure energy.

The communication module 103 is configured to perform communication with a database and another terminal.

Specific connection media between the foregoing memory 101, communication module 103, and processor 102 are not limited in the embodiments of the present disclosure. In the embodiments of the present disclosure, in FIG. 7, the memory 101 is connected to the processor 102 by a bus 104. The bus 104 is represented by a thick line in FIG. 7, and connection manners between other parts are only schematically described, but do not constitute any limitation. The bus 104 may be an address bus, a data bus, a control bus or the like. For ease of representation, the bus is only represented by one thick line in FIG. 7, but it does not mean that there is only one bus or one type of bus.

Apparently, those skilled in the art can make various modifications and variations to the present disclosure without departing from the spirit and scope of the present disclosure. In this way, if these modifications and variations to the present disclosure fall within the scope of claims of the present disclosure and equivalent technologies thereof, the present disclosure also intends to cover these modifications and variations.

What is claimed is:

1. A method for manufacturing a semiconductor device, comprising:
providing a semiconductor wafer, and acquiring surface flatness information of the semiconductor wafer;
determining an exposure parameter of the semiconductor wafer according to the surface flatness information of the semiconductor wafer; and
exposing the semiconductor wafer according to the exposure parameter.

2. The method of claim 1, wherein the semiconductor wafer has a preset exposure parameter, and determining the exposure parameter of the semiconductor wafer according to the surface flatness information of the semiconductor wafer comprises: modifying the preset exposure parameter according to the surface flatness information to obtain the exposure parameter.

3. The method of claim 2, wherein the preset exposure parameter comprises a first focus depth and first exposure energy that are preset according to a target critical dimension (CD); and modifying the preset exposure parameter according to the surface flatness information to obtain the exposure parameter comprises: modifying the first focus depth into a second focus depth according to the surface flatness information, and modifying the first exposure energy into second exposure energy according to the target CD and the second focus depth.

4. The method of claim 3, wherein exposing the semiconductor wafer according to the exposure parameter comprises:
exposing the semiconductor wafer according to the second focus depth and the second exposure energy.

5. The method of claim 2, wherein the semiconductor wafer comprises a plurality of exposure regions, and acquiring surface flatness information of the semiconductor wafer comprises:
acquiring the surface flatness information of the exposure regions of the semiconductor wafer.

6. The method of claim 5, wherein each of the exposure regions has the preset exposure parameter; and modifying the preset exposure parameter according to the surface flatness information to obtain the exposure parameter comprises: modifying the preset exposure parameters of the exposure regions respectively according to the surface flatness information of the exposure regions.

7. A method for exposing a semiconductor, comprising:
providing a semiconductor wafer, and acquiring surface flatness information of the semiconductor wafer;
exposing the semiconductor wafer under a preset exposure condition to acquire a feature pattern;
measuring the feature pattern to acquire a feature dimension of the feature pattern; and
determining whether the feature dimension satisfies a preset condition; when the feature dimension satisfies the preset condition, continuing to expose a subsequent semiconductor wafer according to the preset exposure condition; and when the feature dimension does not satisfy the preset condition, selecting a feature pattern having an outlier feature dimension, finding a surface flatness corresponding to a region of the feature pattern, modifying the preset exposure condition of the feature pattern having the outlier feature dimension according to the surface flatness, and exposing the subsequent semiconductor wafer according to the modified preset exposure condition.

8. The method of claim 7, wherein the preset exposure condition comprises a first focus depth and first exposure energy that are preset according to a target critical dimension (CD); and modifying the preset exposure condition of the feature pattern having the outlier feature dimension according to the surface flatness comprises:
modifying the first focus depth of the feature pattern having the outlier feature dimension into a second focus depth according to the surface flatness information, and modifying the first exposure energy of the feature pattern having the outlier feature dimension into second exposure energy according to the target CD and the second focus depth.

9. The method of claim 8, wherein exposing the subsequent semiconductor wafer according to the modified preset exposure condition comprises:
exposing the subsequent semiconductor wafer according to the second focus depth and the second exposure energy.

10. The method of claim 7, wherein the semiconductor wafer comprises a plurality of exposure regions, and the exposure regions have respective preset exposure conditions; and finding a surface flatness corresponding to a region of the feature pattern, modifying the preset exposure condition of the feature pattern having the outlier feature dimension according to the surface flatness, and exposing the subsequent semiconductor wafer according to the modified preset exposure condition comprises:
acquiring surface flatness information of the exposure regions corresponding to the region of the feature pattern respectively, and modifying the preset exposure conditions of the exposure regions corresponding to the feature pattern having the outlier feature dimension respectively according to the surface flatness information of the exposure regions corresponding to the region of the feature pattern;
exposing the subsequent semiconductor wafer according to the modified preset exposure condition.

11. An apparatus for manufacturing a semiconductor device according to claim 1, comprising:
a processor, configured to acquire surface flatness information of a semiconductor wafer after the semiconductor wafer is provided, and determine an exposure parameter of the semiconductor wafer according to the surface flatness information of the semiconductor wafer; and
an exposure implementation device, configured to expose the semiconductor wafer according to the exposure parameter.

12. The apparatus for manufacturing a semiconductor device of claim 11, wherein the semiconductor wafer has a preset exposure parameter, and the parameter determination unit is configured to modify the preset exposure parameter according to the surface flatness information to obtain the exposure parameter.

13. The apparatus for manufacturing a semiconductor device of claim 12, wherein the preset exposure parameter comprises a first focus depth and first exposure energy that are preset according to a target critical dimension (CD); and the parameter determination unit is configured to: modify the first focus depth into a second focus depth according to the surface flatness information, and modify the first exposure energy into second exposure energy according to the target CD and the second focus depth.

14. The apparatus for manufacturing a semiconductor device of claim 12, wherein the semiconductor wafer comprises a plurality of exposure regions; and the information acquisition unit is configured to acquire the surface flatness information of the exposure regions of the semiconductor wafer.

15. The apparatus for manufacturing a semiconductor device of claim 14, wherein each of the exposure regions has the preset exposure parameter; and the parameter determination unit is configured to modify the preset exposure parameters of the exposure regions respectively according to the surface flatness information of the exposure regions.

16. A system for exposing a semiconductor, comprising:
a memory, configured to store data or program codes used to run the semiconductor exposure system; and
a processor, configured to: provide a semiconductor wafer, and acquire surface flatness information of the semiconductor wafer;
expose the semiconductor wafer under a preset exposure condition to acquire a feature pattern;
measure the feature pattern to acquire a feature dimension of the feature pattern; and
determine whether the feature dimension satisfies a preset condition; when the feature dimension satisfies the preset condition, continue to expose the subsequent semiconductor wafer according to the preset exposure condition; and when the feature dimension does not satisfy the preset condition, select a feature pattern having an outlier feature dimension, find a surface flatness corresponding to a region of the feature pattern, modify the preset exposure condition of the feature pattern having the outlier feature dimension according to the surface flatness, and expose the subsequent semiconductor wafer according to the modified preset exposure condition.

17. The system of claim 16, wherein the preset exposure condition comprises a first focus depth and first exposure energy that are preset according to a target critical dimension (CD); and the processor is configured to:
modify the first focus depth of the feature pattern having the outlier feature dimension into a second focus depth according to the surface flatness information, modify the first exposure energy of the feature pattern having the outlier feature dimension into second exposure energy according to the target CD and the second focus depth.

18. The system of claim 17, wherein the processor is configured to:
expose the subsequent semiconductor wafer according to the second focus depth and the second exposure energy.
